(19) United States
(12) Patent Application Publication
(10) Pub. No.: US 2025/0132217 A1
(43) Pub. Date: Apr. 24, 2025

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Wen-Ting LAN, Hsinchu (TW); Shih-Cheng CHEN, Hsinchu (TW); Chia-Cheng TSAI, Hsinchu (TW); Kuo-Cheng CHIANG, Hsinchu (TW)

(73) Assignee: Taiwan Semiconductor Manufacturing Company, Ltd., Hsinchu (TW)

(21) Appl. No.: 18/381,706

(22) Filed: Oct. 19, 2023

(51) Int. Cl. H01L 23/31; H01L 29/423; H01L 29/66; H01L 29/775; H01L 29/786

(52) U.S. Cl. CPC H01L 23/3192; H10D 30/014; H10D 30/031; H10D 30/43; H10D 30/6735; H10D 30/6757; H10D 64/017

(57) ABSTRACT

A semiconductor device includes a substrate, an active structure, a first dielectric layer and a second dielectric layer. The active structure is formed on the substrate and includes an active channel sheet, wherein the active channel sheet has a first lateral surface. The first dielectric layer is formed above the active structure and has a recess, wherein the recess is recessed with respect to the first lateral surface of the active channel sheet. The second dielectric layer is formed within the recess and has a dielectric constant, wherein the dielectric constant is less than 3.9.

### BACKGROUND

In semiconductor device, a Critical Dimension (CD) between two active structures gets smaller and smaller, and thus the nodules are easily to remain on a sidewall of a dummy gate above the active structure in epitaxy process. The nodule will obstruct material formed subsequently. Thus, how to clean the nodule is one of the goals of the industry in this technical field.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic diagram of a cross-sectional view of a semiconductor device 100 according to an embodiment of the present disclosure.

FIG. 2 illustrates a schematic diagram of a cross-sectional view of a semiconductor device 200 according to an embodiment of the present disclosure; and

FIGS. 3A to 3H illustrate schematic diagrams of manufacturing processes of the semiconductor device 100 in FIG. 1.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

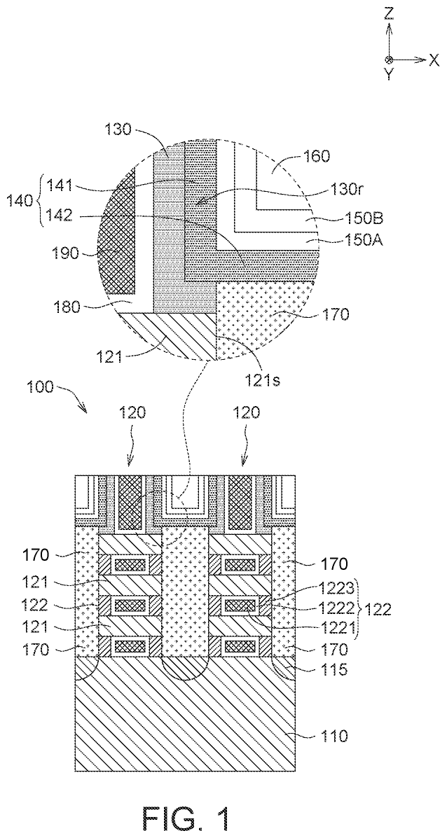

Referring to FIG. 1, FIG. 1 illustrates a schematic diagram of a cross-sectional view of a semiconductor device 100 according to an embodiment of the present disclosure. The semiconductor device 100 includes a substrate 110, at least one pure silicon layer 115, at least one active structure 120, at least one first dielectric layer 130, at least one second dielectric layer 140, at least one first contact etch stop layer (CESL) 150A, at least one second CESL 150B, at least one oxide layer 160, at least one epitaxy layer 170, at least one high-k dielectric layer 180 and at least one metal gate 190.

As illustrated in FIG. 1, the active structure 120 is formed on the substrate 110 and includes at least one active channel sheet 121, wherein each active channel sheet 121 has a first lateral surface 121s. The first dielectric layer 130 is formed on the active structure 120 and has a recess 130r recessed with respect to the lateral surface 121s of the active channel sheet 121. The second dielectric layer 140 is partially formed within the recess 130r. The second dielectric layer 140 has a dielectric constant, and the dielectric constant is less than 3.9. Due to the second dielectric layer 140 having lower dielectric constant, the parasitic capacitance of the semiconductor device 100 may be reduced by at least 1.7%. Furthermore, the second dielectric layer 140 is, for example, a low-K dielectric layer.

As illustrated in FIG. 1, the substrate 110 is formed of a material including silicon. The substrate 110 is, for example, silicon wafer. The pure silicon layer 115 is formed within adjacent two of the active structures 120, and between the pure silicon layer 115 and the epitaxy layer 170.

As illustrated in FIG. 1, each active structure 120 includes a plurality of the active channel sheet 121 and a plurality of spacers (or composite layers) 122. Each spacer 122 is formed between adjacent two of the active channel sheets 121. Each spacer 122 includes a metal portion 1221, a high-k dielectric portion 1222 and an inner spacer 1223, wherein the metal portion 1221 may be surrounded by the high-k dielectric portion 1222, the high-k dielectric portion 1222 covers a portion of the active channel sheet 121, the inner spacer 1223 is formed on a lateral surface of the high-k dielectric portion 1222 or the active channel sheet 121. In addition, the metal portion 1221 may be formed of a material the same as that of the metal gate 190, and the metal portion 1221 and the metal gate 190 may be formed in the same process. The high-k dielectric portion 1222 may be formed of a material the same as that of the high-k dielectric layer 180, and the high-k dielectric portion 1222 and the high-k dielectric layer 180 may be formed in the same process.

As illustrated in FIG. 1, the first dielectric layer 130 has a second lateral surface 130s, and the first lateral surface 121s and the second lateral surface 130s are substantially flushed with each other.

The first dielectric layer 130 may be formed of a material different from that of the second dielectric layer 140. In an embodiment, the first dielectric layer 130 may be formed from a material including one of SiO, SiN, SiOC, SiON and SiOCN, and the second dielectric layer 140 may be formed from a material including another of SiO, SiN, SiOC, SiON and SiOCN. In an embodiment, the first dielectric layer 130 may have a thickness ranging between, for example, 1 nanometers (nm) and 10 nm, and the second dielectric layer 140 may have a thickness ranging between, for example, 1 nm and 10 nm.

As illustrated in FIG. 1, the second dielectric layer 140 is, for example, a contiguous single layer. The second dielectric layer 140 includes a first portion 141 and a second portion 142. The first portion 141 formed within the recess 130r and extends in a first direction Z, and the second portion 142 is connected with the first portion 141 and extends in a second direction X perpendicular to the first direction Z. The second dielectric layer 140 protrudes beyond the first lateral surface 121s of the active channel sheet 121. Furthermore, the second portion 142 of the second dielectric layer 140 protrudes beyond the first lateral surface 121s of the active channel sheet 121. In the present embodiment, the second dielectric layer 140 is formed between the epitaxy layer 170 and the first CESL 150A. Furthermore, the second portion 142 of the second dielectric layer 140 is formed between the epitaxy layer 170 and the first CESL 150A. The second portion 142 is formed over/above the epitaxy layer 170.

As illustrated in FIG. 1, the first CESL 150A is formed on the second dielectric layer 140. The first CESL 150A may be formed from a material including SiO, SiN, SiOC, SiON or SiOCN. The first CESL 150A may have a thickness ranging between, for example, 1 nm and 10 nm. The second CESL 150B is formed on the first CESL 150A. Furthermore, the second CESL 150B is formed between the first CESL 150A and the oxide layer 160. The second CESL 150B may be formed from a material including SiO, SiN, SiOC, SiON or SiOCN. The second CESL 150B may have a thickness ranging between, for example, 1 nm and 10 nm. The oxide layer 160 is formed on the second CESL 150B.

As illustrated in FIG. 1, in the present embodiment, the first CESL 150A may be separated from the epitaxy layer 170 by the second dielectric layer 140. In other words, the first CESL 150A is not directly contact in the epitaxy layer 170. In addition, the first CESL 150A may be separated from the first dielectric layer 130 by the second dielectric layer 140. In other words, the first CESL 150A is not directly contact in the first dielectric layer 130.

As illustrated in FIG. 1, the epitaxy layer 170 is formed between adjacent two of the active structures 120. The epitaxy layer 170 may be a source or a drain of a transistor. The transistor may include one metal gate 190 and two epitaxy layers 170 formed opposite two sides of the active structures 120. The high-k dielectric layer 180 is formed between the metal gate 190 and the first dielectric layer 130.

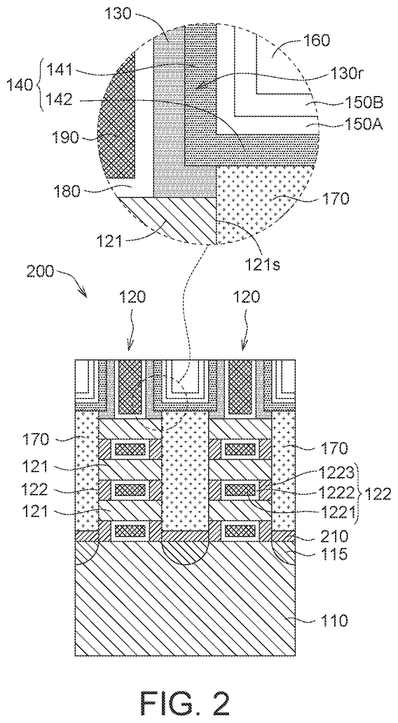

Referring to FIG. 2, FIG. 2 illustrates a schematic diagram of a cross-sectional view of a semiconductor device 200 according to an embodiment of the present disclosure. The semiconductor device 200 includes the substrate 110, at least one pure silicon layer 115, at least one active structure 120, at least one first dielectric layer 130, at least one second dielectric layer 140, at least one first CESL 150A, at least one second CESL 150B, at least one oxide layer 160, at least one epitaxy layer 170, at least one high-k dielectric layer 180, at least one metal gate 190 and at least one isolation layer 210. The active structure 120 is formed on the substrate 110 and includes at least one active channel sheet 121, wherein the active channel sheet 121 has the first lateral surface 121s. The first dielectric layer 130 is formed on the active structure 120 and has the recess 130r recessed with respect to the lateral surface 121s of the active channel sheet 121. The second dielectric layer 140 is formed within the recess 130r. The second dielectric layer has a dielectric constant, and the dielectric constant is less than 3.9. Due to the second dielectric layer 140 having lower dielectric constant, the parasitic capacitance of the semiconductor device 100 may be reduced by at least 1.7%. Furthermore, the second dielectric layer 140 is, for example, a low-K dielectric layer.

As illustrated in FIG. 2, the isolation layer 210 is formed between the epitaxy layer 170 and the pure silicon layer 115 for electrically isolating the epitaxy layer 170 from the pure silicon layer 115 (or the substrate 110), and accordingly it may reduce the current leakage to the pure silicon layer 115 (or the substrate 110).

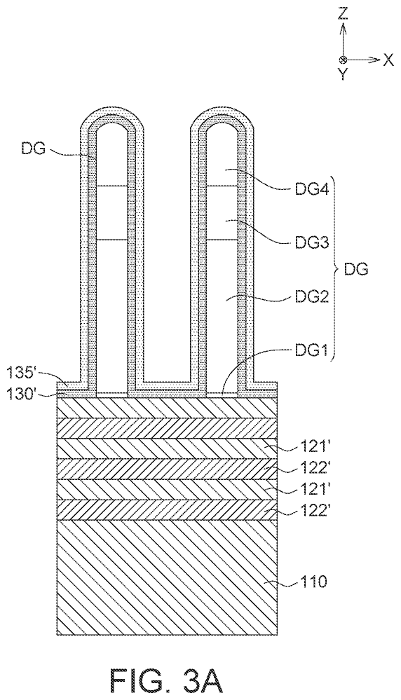

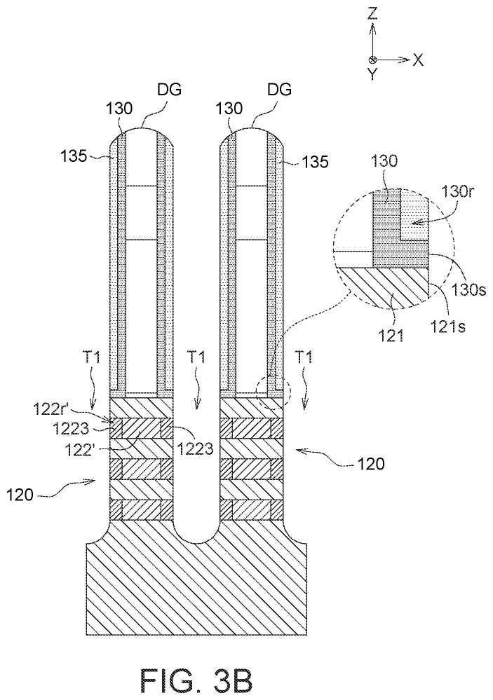

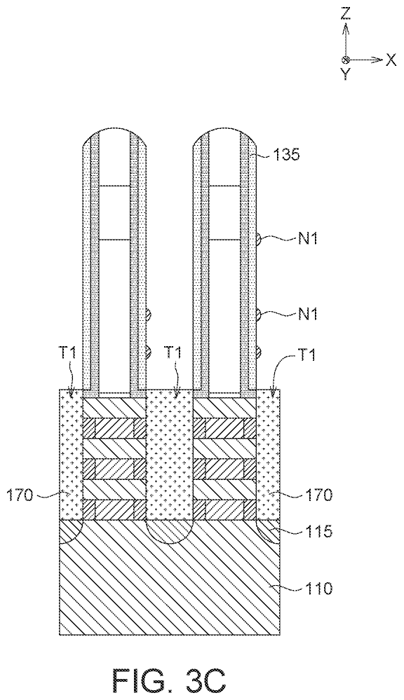

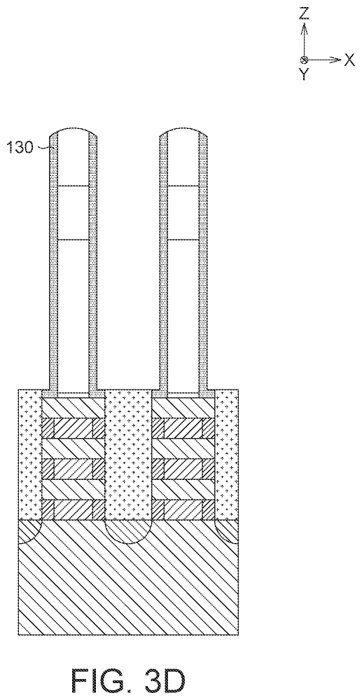

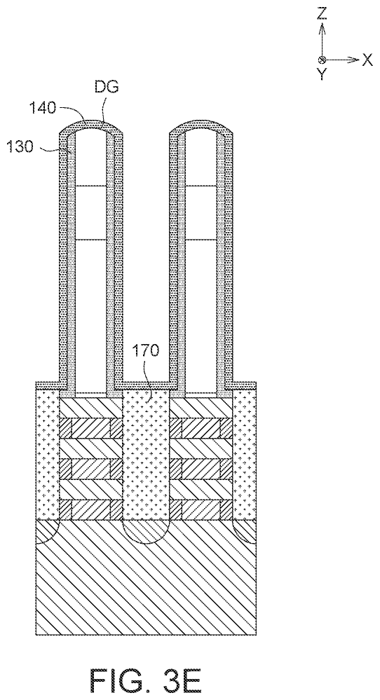

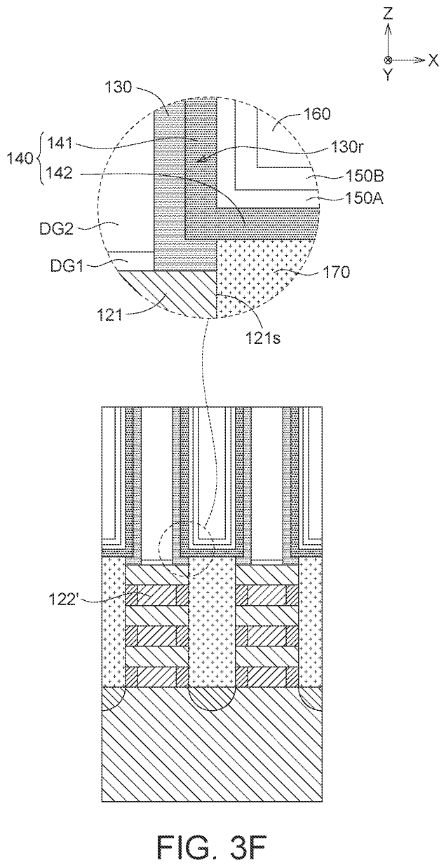

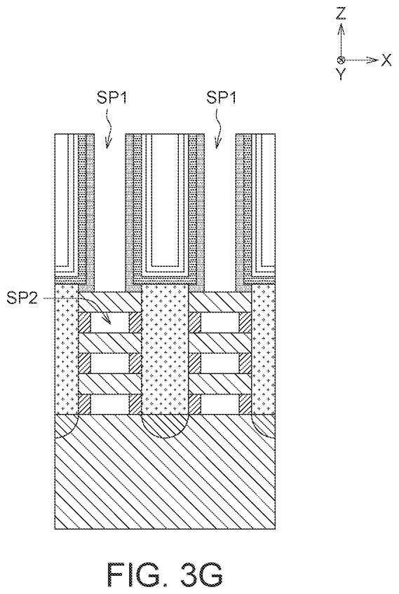

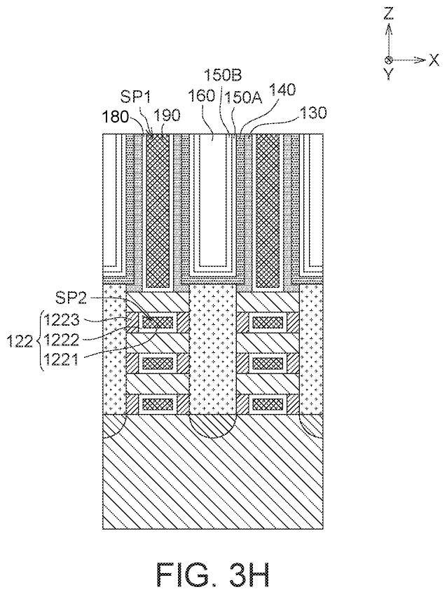

FIGS. 3A to 3H illustrate schematic diagrams of manufacturing processes of the semiconductor device 100 in FIG. 1.

As illustrated in FIG. 3A, a super lattice structure (stack structure) including, for example, a plurality of active channel sheet layers 121′ and a plurality of spacer layers 122′ is formed on the substrate 110, wherein one of the spacer layers 122′ is formed between the adjacent two of the active channel sheet layers 121′. The spacer layer 122′ may be formed of a material including, for example, silicon germanium, and the active channel sheet layer 121′ may be formed of a material including, for example, silicon.

In addition, a portion of the superlattice structure may be removed to form a plurality of fin structures each extending in X-direction, and a plurality of the fin structures are arranged in Y-direction. The region of one fin structure defines one (Oxide definition, OD) region, for example.

As illustrated in FIG. 3A, at least one dummy gate structure DG is formed on the superlattice structure. The dummy gate structure DG includes a dummy dielectric layer DG1, a dummy gate layer DG2, a mask layer DG3 and an oxide layer DG4. The dummy dielectric layer DG1 is formed on the fin structures. The dummy dielectric layer DG1 is formed of a material including, for example, silicon oxide, silicon nitride, a combination thereof, or the like, and may be deposited or thermally grown according to acceptable techniques. The dummy gate layer DG2 is formed over the dummy dielectric layer DG1, and the mask layer DG3 is formed over the dummy gate layer DG2. The dummy gate layer DG2 may be deposited over the dummy dielectric layer DG1 and then planarized, such as by CMP. The mask layer DG3 may be deposited over the dummy gate layer DG2. The dummy gate layer DG2 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer DG2 may be deposited by physical vapor deposition (PVD), CVD, sputter deposition, or other techniques for depositing the selected material. The dummy gate layer DG2 may be formed of other materials that have a high etching selectivity from the etching of isolation regions. The mask layer DG3 may include, for example, silicon nitride, silicon oxynitride, or the like.

As illustrated in FIG. 3A, a first dielectric layer material 130′ covering the dummy gate structures DG is formed by using, for example, deposition. Then, a third dielectric layer material 135′ covering the first dielectric layer material 130′ is formed by using, for example, deposition. The first dielectric layer material 130′ and the third dielectric layer material 135′ are different in material for obtaining different selectivity ratios. Furthermore, the first dielectric layer material 130′ may be formed from a material including one of SiO, SiN, SiOC, SiON and SiOCN, and the third dielectric layer material 135′ may be formed from a material including another of SiO, SiN, SiOC, SiON and SiOCN. In addition, the first dielectric layer material 130′ may have a thickness ranging between, for example, 1 nm and 10 nm, and the third dielectric layer material 135′ may have a thickness ranging between, for example, 1 nm and 10 nm.

Then, as illustrated in FIG. 3B, a portion of the fin structures, a portion of the first dielectric layer material 130′ and a portion of the third dielectric layer material 135′ is removed to form a plurality of the active structures 120, a plurality of the first dielectric layers 130 and a plurality of third dielectric layers 135, through the dummy gate structures DG, by etching, wherein there is a trench T1 formed between adjacent two of the active structures 120. Each active structure 120 includes a plurality of the active channel sheets 121 and a plurality of the spacer layers 122′ stacked to each other. After the trench T1 is formed, the active channel sheet 121 forms the first lateral surface 121s, the first dielectric layers 130 forms the second lateral surface 130s, and the first lateral surface 121s and the second lateral surface 130s are flushed with each other. In addition, after the trench T1 is formed, the recess 130r recessed with respect to the second lateral surface 130s or the first lateral surface 121s is formed.

Then, as illustrated in FIG. 3B, a plurality of recesses 122r′ is formed on the spacer layers 122′ in FIG. 3A by using, for example, etching, and then a plurality of inner spacer 1223 are formed within the recesses 122r′ and cover sidewalls of the spacer layers 122′.

As illustrated in FIG. 3C, at least one pure silicon layer 115 is formed (or backfills) within a bottom of the corresponding trench T1 by using, for example, epitaxy process. Then, a plurality of the epitaxies 170 is formed on the pure silicon layers 115 within the trenches T1 by using, for example, epitaxy process. In epitaxy process, a plurality of nodules N1 (for example, amorphous Si or SiGe) may be formed on or remain on sidewall of the third dielectric layer 135.

As illustrated in FIG. 3D, the third dielectric layers 135 in FIG. 3C are removed by, for example, etching, or wet cleaning. After etching, all nodules N1 on the third dielectric layers 135 may be removed from the structure in FIG. 3C. In an embodiment, all third dielectric layers 135 are removed, and accordingly all nodule N1 may be cleaned with the removing of the third dielectric layers 135. Due to the nodule N1 being removed, the material (for example, the CESL material, etc.) in subsequent process is not obstructed by the nodule N1.

As illustrated in FIG. 3E, the second dielectric layer 140 covering the dummy gate structures DG, the first dielectric layers 130 and the epitaxies 170 is formed by using, for example, deposition.

As illustrated in FIG. 3F, the second dielectric layer 140 covering the epitaxies 170 and the first dielectric layer 130 is formed by using, for example, deposition. Then, the first CESL 150A covering the second dielectric layer 140 is formed by using, for example, deposition. Then, the second CESL 150B covering the first CESL 150A is formed by using, for example, deposition. Then, the oxide layer 160 covering the second CESL 150B is formed by using, for example, deposition.

In FIG. 3F, the second dielectric layer 140 includes the first portion 141 and the second portion 142. The first portion 141 is formed within the recess 130r and extends in the first direction Z, and the second portion 142 is connected with the first portion 141 and extends in the second direction X perpendicular to the first direction Z. The second dielectric layer 140 protrudes beyond the first lateral surface 121s of the active channel sheet 121. Furthermore, the second portion 142 of the second dielectric layer 140 protrudes beyond the first lateral surface 121s of the active channel sheet 121.

As illustrated in FIG. 3G, the spacer layers 122′ and the dummy gate structures DG are removed to form a plurality of first spaces SP1 and a plurality of second spaces SP2 by using, for example, etching.

As illustrated in FIG. 3H, at least one high-k dielectric portion 1222 within the corresponding second space SP2 and covering a portion of the corresponding active channel sheet 121 and the corresponding inner spacer 1223 is formed by, for example, deposition. at least one high-k dielectric layer 180 within the corresponding first space SP1 and covering the corresponding first dielectric layer 130 and the topmost active channel sheet 121 is formed by, for example, deposition. The high-k dielectric portion 1222 and the high-k dielectric layer 180 may be formed in the same process.

Then, as illustrated in FIG. 3H, at least one metal gate 190 within the corresponding first space SP1 and at least one metal portion 1221 within the corresponding second space SP2 are formed by using, for example, deposition. The metal gate 190 is formed around the active channel sheet 121 (for example, viewed in X-direction), and such structure is also called “Gate-All-Around (GAA) structure”.

Then, the first dielectric layer 130, the second dielectric layer 140, the first CESL 150A, the second CESL 150B and the oxide layer 160 are planarized by using, for example, the CMP (Chemical mechanical polishing).

A manufacturing method for the semiconductor device 200 including the processes the same as or similar to that of the semiconductor device 100, and the difference is that the isolation layer 210 is formed on the pure silicon layer 115 after the pure silicon layer 115 is formed.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

According to the present disclosure, a semiconductor device includes a substrate, an active structure and two dielectric layers. The active structure is formed on the substrate and includes an active channel sheet. The dielectric layers are formed above the active structure. One of the dielectric layers has a dielectric constant, wherein the dielectric constant is less than 3.9. Due to the dielectric layer having lower dielectric constant (for example, the low-K dielectric layer), the parasitic capacitance of the semiconductor device may be reduced by at least 1.7%.

Example embodiment 1: a semiconductor device includes a substrate, an active structure, a first dielectric layer and a second dielectric layer. The active structure is formed on the substrate and includes an active channel sheet, wherein the active channel sheet has a first lateral surface. The first dielectric layer is formed above the active structure and has a recess, wherein the recess is recessed with respect to the first lateral surface of the active channel sheet. The second dielectric layer is formed within the recess and has a dielectric constant, wherein the dielectric constant is less than 3.9.

Example embodiment 2 based on Example embodiment 1: the first dielectric layer has a second lateral surface, and the first lateral surface and the second lateral surface are flushed with each other.

Example embodiment 3 based on Example embodiment 1: the first dielectric layer is formed of a material different from that of the second dielectric layer.

Example embodiment 4 based on Example embodiment 1: the second dielectric layer includes a first portion and a second portion. The first portion is formed within the recess and extends in a first direction. The second portion is connected with the first portion and extends in a second direction perpendicular to the first direction.

Example embodiment 5 based on Example embodiment 1: the semiconductor device includes a plurality of the active structures. The semiconductor device further includes an epitaxy layer formed between adjacent two of the active structures. The second dielectric layer includes a first portion and a second portion. The first portion is formed within the recess. The second portion is connected with the first portion and formed over the epitaxy layer.

Example embodiment 6 based on Example embodiment 1: the second dielectric layer protrude beyond the first lateral surface of the active channel sheet.

Example embodiment 7 based on Example embodiment 1: the semiconductor device includes a plurality of the active structures. The semiconductor device further includes an epitaxy layer and an isolation layer. The epitaxy layer is formed between adjacent two of the active structures. The isolation layer is formed between the epitaxy layer and the substrate.

Example embodiment 8: a semiconductor device includes a substrate, a plurality of active structures, an epitaxy layer, a first dielectric layer and a second dielectric layer. The active structures are formed on the substrate. The epitaxy layer is formed between adjacent two of the active structures. The first dielectric layer is formed above the corresponding active structure and has a recess. The second dielectric layer is formed within the recess and over the epitaxy layer. The second dielectric layer is a contiguous single layer.

Example embodiment 9 based on Example embodiment 8: each active structure includes an active channel sheet having a first lateral surface, the first dielectric layer has a second lateral surface, and the corresponding first lateral surface and the second lateral surface are flushed with each other.

Example embodiment 10 based on Example embodiment 8: the epitaxy layer formed between adjacent two of the active structures. The second dielectric layer includes a first portion and a second portion. The first portion is formed within the recess. The second portion is connected with the first portion and formed over the epitaxy layer.

Example embodiment 11 based on Example embodiment 8: the first dielectric layer is formed of a material different from that of the second dielectric layer.

Example embodiment 12 based on Example embodiment 8: the second dielectric layer includes a first portion and a second portion. The first portion is formed within the recess and extends in a first direction. The second portion is connected with the first portion and extends in a second direction perpendicular to the first direction.

Example embodiment 13 based on Example embodiment 8: the semiconductor device further includes an isolation layer. The epitaxy layer is formed between adjacent two of the active structures. The isolation layer is formed between the epitaxy layer and the substrate.

Example embodiment 14: a manufacturing method for a semiconductor device includes the following steps: forming a stack structure on a substrate, wherein the stack structure includes an active channel sheet; forming a first dielectric layer material over the stack structure; removing a portion of the stack structure and a portion of the first dielectric layer material to form an active structure and a first dielectric layer, wherein the active structure includes an active channel sheet having a first lateral surface, and the first dielectric layer has a recess recessed with respect to the first lateral surface of the active channel sheet; and forming a second dielectric layer within the recess, wherein the second dielectric layer has a dielectric constant less than 3.9.

Example embodiment 15 based on Example embodiment 14: the manufacturing method further includes forming a third dielectric layer over the first dielectric layer; and forming an epitaxy layer adjacent to the active structure. After forming the epitaxy layer adjacent to the active structure, the manufacturing method further includes removing the third dielectric layer.

Example embodiment 16 based on Example embodiment 15: in forming the third dielectric layer over the first dielectric layer, the third dielectric layer is formed of a material different from that of the first dielectric layer material.

Example embodiment 17 based on Example embodiment 14: in removing the portion of the stack structure and the portion of the first dielectric layer material to form the active structure and the first dielectric layer, the first lateral surface and the second lateral surface are flushed with each other.

Example embodiment 18 based on Example embodiment 14: in removing the portion of the stack structure and the portion of the first dielectric layer material to form the active structure and the first dielectric layer, there is a trench between adjacent two of a plurality of the active structures; the manufacturing method further includes forming an isolation layer on a bottom of the trench. In forming the epitaxy layer adjacent to the active structure, the epitaxy layer is formed on the isolation.

Example embodiment 19 based on Example embodiment 14: in forming the second dielectric layer within the recess, the second dielectric layer includes a first portion and a second portion, the first portion is formed within the recess and extends in a first direction, and the second portion is connected with the first portion and extends in a second direction perpendicular to the first direction.

Example embodiment 20 based on Example embodiment 14: in forming the second dielectric layer within the recess, the second dielectric layer protrude beyond the first lateral surface of the active channel sheet.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
an active structure formed on the substrate and comprising an active channel sheet, wherein the active channel sheet has a first lateral surface;
a first dielectric layer formed above the active structure and having a recess, wherein the recess is recessed with respect to the first lateral surface of the active channel sheet; and
a second dielectric layer formed within the recess and having a dielectric constant, wherein the dielectric constant is less than 3.9.

2. The semiconductor device as claimed in claim 1, wherein the first dielectric layer has a second lateral surface, and the first lateral surface and the second lateral surface are flushed with each other.

3. The semiconductor device as claimed in claim 1, wherein the first dielectric layer is formed of a material different from that of the second dielectric layer.

4. The semiconductor device as claimed in claim 1, wherein the second dielectric layer comprises:
a first portion formed within the recess and extending in a first direction; and
a second portion connected with the first portion and extending in a second direction perpendicular to the first direction.

5. The semiconductor device as claimed in claim 1, wherein the semiconductor device comprises a plurality of the active structures; the semiconductor device further comprising:
an epitaxy layer formed between adjacent two of the active structures;
wherein the second dielectric layer comprises:
a first portion formed within the recess; and
a second portion connected with the first portion and formed over the epitaxy layer.

6. The semiconductor device as claimed in claim 1, wherein the second dielectric layer protrude beyond the first lateral surface of the active channel sheet.

7. The semiconductor device as claimed in claim 1, wherein the semiconductor device comprises a plurality of the active structures; the semiconductor device further comprising:
an epitaxy layer formed between adjacent two of the active structures; and
an isolation layer formed between the epitaxy layer and the substrate.

8. A semiconductor device, comprising:
a substrate;
a plurality of active structures formed on the substrate;
an epitaxy layer formed between adjacent two of the active structures;
a first dielectric layer formed above the corresponding active structure and having a recess; and
a second dielectric layer formed within the recess and over the epitaxy layer;
wherein the second dielectric layer is a contiguous single layer.

9. The semiconductor device as claimed in claim 8, wherein each active structure comprises an active channel sheet having a first lateral surface, the first dielectric layer has a second lateral surface, and the corresponding first lateral surface and the second lateral surface are flushed with each other.

10. The semiconductor device as claimed in claim 8, wherein the second dielectric layer comprises:
a first portion formed within the recess; and
a second portion connected with the first portion and formed over the epitaxy layer.

11. The semiconductor device as claimed in claim 8, wherein the first dielectric layer is formed of a material different from that of the second dielectric layer.

12. The semiconductor device as claimed in claim 8, wherein the second dielectric layer comprises:
a first portion formed within the recess and extending in a first direction; and
a second portion connected with the first portion and extending in a second direction perpendicular to the first direction.

13. The semiconductor device as claimed in claim 8, further comprising:
an isolation layer formed between the epitaxy layer and the substrate.

14. A manufacturing method for a semiconductor device, comprising:
forming a stack structure on a substrate, wherein the stack structure comprises an active channel sheet layer;
forming a first dielectric layer material over the stack structure;
removing a portion of the stack structure and a portion of the first dielectric layer material to form an active structure and a first dielectric layer, wherein the active structure comprises an active channel sheet having a first lateral surface, and the first dielectric layer has a recess recessed with respect to the first lateral surface of the active channel sheet; and
forming a second dielectric layer within the recess, wherein the second dielectric layer has a dielectric constant less than 3.9.

15. The manufacturing method as claimed in claim 14, further comprising:
forming a third dielectric layer over the first dielectric layer; and
forming an epitaxy layer adjacent to the active structure;
wherein after forming the epitaxy layer adjacent to the active structure, the manufacturing method further comprises:
removing the third dielectric layer.

16. The manufacturing method as claimed in claim 15, wherein in forming the third dielectric layer over the first dielectric layer, the third dielectric layer is formed of a material different from that of the first dielectric layer material.

17. The manufacturing method as claimed in claim 14, wherein in removing the portion of the stack structure and the portion of the first dielectric layer material to form the active structure and the first dielectric layer, the first lateral surface and the second lateral surface are flushed with each other.

18. The manufacturing method as claimed in claim 14, wherein in removing the portion of the stack structure and the portion of the first dielectric layer material to form the active structure and the first dielectric layer, the semiconductor device comprises a plurality of the active structures and there is a trench between adjacent two of a plurality of the active structures; the manufacturing method further comprising:
forming an isolation layer on a bottom of the trench;
wherein in forming the epitaxy layer adjacent to the active structure, the epitaxy layer is formed on the isolation.

19. The manufacturing method as claimed in claim 14, wherein in forming the second dielectric layer within the recess, the second dielectric layer comprises a first portion and a second portion, the first portion is formed within the recess and extends in a first direction, and the second portion is connected with the first portion and extends in a second direction perpendicular to the first direction.

20. The manufacturing method as claimed in claim 14, wherein in forming the second dielectric layer within the recess, the second dielectric layer protrude beyond the first lateral surface of the active channel sheet.
